(19) United States
(12) Patent Application Publication
(10) Pub. No.: US 2003/0185980 A1
(43) Pub. Date: Oct. 2, 2003

(54) Thin film forming method and a semiconductor device manufacturing method

(75) Inventor: Kazuhiko Endo, Tokyo (JP)

Correspondence Address: SUGHRUE MION, PLLC, 2100 PENNSYLVANIA AVENUE, N.W., WASHINGTON, DC, 20037, US

(73) Assignee: NEC CORPORATION

(21) Appl. No.: 10/401,970

(22) Filed: Mar. 31, 2003

(30) Foreign Application Priority Data
Apr. 1, 2002 (JP) 099262/2002

(51) Int. Cl. H05H 1/24; H01L 21/44

(52) U.S. Cl. 427/255.23; 427/576; 438/683

(57) ABSTRACT

A thin film forming method characterized by at least a first step and a second step which steps may be repeated. The first step is the step of supplying a compound containing at least one kind of metal element onto a substrate, and the second step is the step of irradiating the substrate with energy particles in order to introduce the metal element into the substrate. A semiconductor device manufacturing method of the present invention uses the thin film forming method described above in the manufacturing of a semiconductor device.

### BACKGROUND OF THE INVENTION

1. Fields of the Invention

The present invention relates to a new thin film forming method for forming a thin film such a silicide film, a silicate film and the like for example, and a semiconductor device manufacturing method having the same thin film forming method in a process.

2. Description of the Related Art

In recent years, in a semiconductor large scale integrated circuit (LSI), due to the increase of integration degree, it has been an important problem in manufacturing an LSI to form various kinds of thin films well in reliability and uniformity on a silicon wafer. Particularly, characteristics such as a low leakage current, a resistivity of high voltage, high reliability; uniformity of film thickness and so on, are demanded for a gate insulating film used in a gate of a field-effect transistor of an MOS (metal oxide semiconductor) type. An SiO2 film deposited by thermal oxidation is used as a conventional gate insulating film, and a polycrystalline silicon electrode deposited by a reduced pressure CVD method is used as a gate electrode provided on the gate insulating film.

However, a gate insulating film in recent years is made into a thin film of 2 nm or less in thickness by the request of the scaling law, and as a result a problem occurs that a gate leakage current increases.

With regard to this problem, it is being studied to newly introduce an insulating film being higher in dielectric constant (referred to as a high-permittivity insulating film also) than an SiO₂ film. Since an insulating film being higher in dielectric constant is made smaller in effective film thickness in case of being converted into a SiO₂ film of 4 in dielectric constant, it has an advantage of being capable of forming an electrically thinner film without increasing a gate leakage current. A high permittivity insulating film needs to be thermodynamically stable relative to a silicon substrate, and from this viewpoint, it is being studied to introduce an Al₂O₃ film, a ZrO₂ film, an HfO₂ film, a lanthanoid oxide film and the like (for example, IEDM Technical Digest 2000, pp. 653, by H, J. Osten). Among them, a ZrO₂ film (25 in dielectric constant), an HfO₂ film (30 in dielectric constant), or a lanthanoid oxide film being high in dielectric constant is thought to be promising.

However, since these high-permittivity insulating films are as low as about 600° C. in crystallization temperature, they are liable to be crystallized and once they are crystallized, a problem occurs that impurities diffuse through crystal grain boundaries and a leakage current occurs.

Due to this, recently a silicate film or an aluminate film is thought to be promising. They can be obtained by adding a metal element capable of suppressing crystallization and of forming a high permittivity insulating film into an SiO₂ film and an Al₂O₃ film.

On the other hand, the uniformity of film thickness of a gate insulating film in a wafer surface is a very important factor. Because it has directly an influence on transistor characteristics such as a threshold voltage, a drain current and the like. For example, the uniformity of film thickness demanded as ±0.1 nm or less (in film thickness measurement in a wafer surface by means of spectro-ellipsometry), in case of depositing a gate insulating film of 1.5 nm in converted film thickness on an 8-inch silicon wafer.

As a method of depositing a gate insulating film having such high film thickness uniformity, various methods are used. For example, they are a reactive sputtering method, a method of sputtering metal and then performing a thermal oxidation process on it, a chemical vapor deposition (CVD) method, an atomic layer deposition (ALD) method and so on.

Particularly, an atomic layer deposition method attracts attention as a powerful deposition method. It is a deposition method of forming a gate insulating film as stacking atomic layers one upon another, can form a gate insulating film having a very uniform film thickness in a silicon wafer. For example, an Al₂O₃ insulating film is deposited by alternately irradiating trimethylaluminum (TMA) and water, and a ZrO₂ insulating film or an HfO₂ film is deposited by alternately irradiating a Zr chloride or an Hf chloride and water.

In case of forming a silicate film or an aluminate film described above, it has been difficult by means of the atomic layer deposition method. In such a conventional atomic layer deposition method, it has not been capable to deposit atomic layers one upon another though it must be supply a silicon material or an aluminum material into a deposition chamber and at the same time supply an organometallic compound which contain a metal element capable of suppressing crystallization and forming a high permittivity insulating film. Due to this, up to now an ordinary thermal CVD method using an organometallic compound or a method of performing a re-oxidation treatment on metal atoms sputtered on a silicon substrate has been adopted as a method of depositing a silicate film or an aluminate film.

However, the in-wafer uniformity of film thickness and film quality of a silicate film or an aluminate film deposited by a thermal CVD method or a sputtering method described above is insufficient, and the improvement of it has been demanded.

### SUMMARY OF THE INVENTION

An object of the present invention is to provide a new thin film forming method for introducing a metal element into a substrate, especially a thin film forming method being capable of forming a thin film composed of a silicide film, a silicate film, an aluminate film or the like on a substrate well in in-wafer uniformity of film thickness and film quality.

And another object of the present invention is, by using the same method, to provide a semiconductor device manufacturing method which makes it possible to improve the integration degree of a semiconductor large scale integrated circuit such as an MOS transistor and the like.

According to a first aspect of the present invention, the thin film forming method is characterized by repeating at least a first step and a second step; the first step of supplying a compound containing at least one kind of metal element onto a substrate, the second step of irradiating the substrate with energy particles in order to introduce the metal element into the substrate.

According to this invention, a compound supplied onto the substrate in the first step is decomposed in the second step and at least one kind of metal element contained in the compound is introduced into the substrate. Since this invention repeats such respective steps, it is possible to introduce a desired amount of specific metal element into a substrate by selecting the number of repetitions. By means of this method, for example, it is possible to form a silicide film by introducing a specific metal element such as tungsten, molybdenum, titanium, tantalum, platinum or the like, or form a high permittivity insulating film composed of a silicate film or an aluminate film by introducing a specific metal element such as zirconium, hafnium, lanthanum or the like into an SiO₂ film or an Al₂O₃ film.

According to another aspect of this invention, a semiconductor device manufacturing is characterized by having a thin film forming method of the present invention. The method can make it possible to form a high permittivity insulating film uniformly in the process. And it is possible to make the integrated circuit such as an MOS transistor and the like improve the integration degree.

### BRIEF DESCRIPTION OF THE DRAWINGS

FIGS. 1(a) to (h) are a flow diagram showing a thin film forming method of the present invention.

FIG. 2 is a schematic diagram of a thin film forming apparatus used in a thin film forming method of the present invention.

FIGS. 3(a) to (h) are a flow diagram showing another example of a thin film forming method of the present invention.

FIG. 4 is a result of examining an effect of adding nitrogen in forming a hafnium silicate film.

FIG. 5 is a diagram showing the distribution in the depth direction of constituent elements of a silicate film.

FIG. 6 is a diagram showing the relation between the hafnium content and thickness of a silicate film and the number of repetitions.

FIG. 7 is a diagram showing the relation between the dielectric constant of a silicate film and the number of repetitions.

FIG. 8 is a diagram showing the relation between the leakage characteristics of a hafnium silicate film and a hafnium aluminate film, and the converted film thickness of them.

FIGS. 9(a) to (d) are schematic sectional views showing the structure of a semiconductor device used in an embodiment of the present invention and a process of manufacturing the same semiconductor device.

FIGS. 10(a) to (c) are schematic sectional views showing another example of the structure of a semiconductor device used in an embodiment of the present invention and a process of manufacturing the same semiconductor device.

### DETAILED DESCRIPTION OF THE INVENTION

A thin film forming method and a semiconductor device manufacturing method of the present invention is described with reference to the drawings in the following.

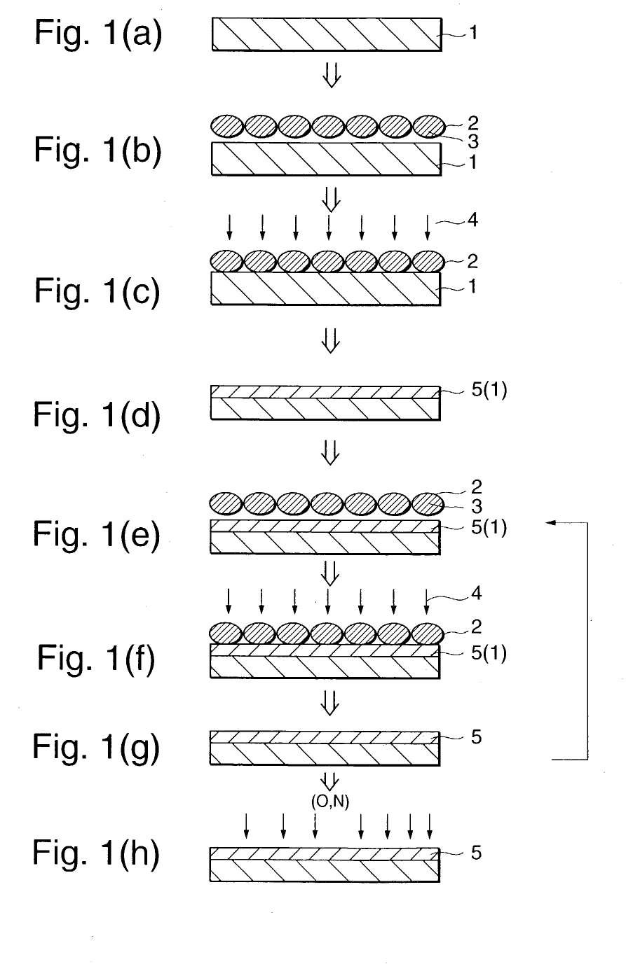

FIG. 1 shows a flow diagram showing a thin film forming method of the present invention. The present invention includes a first step and a second step. The first supplies a compound 2 containing at least one kind of metal element 3 onto a substrate 1 (FIG. 1(b)). And then the second step forms a thin film 5 by irradiating the substrate 1 with energy particles 4 (FIG. 1(c)). At this time the compound 2 supplied onto the substrate 1 in the first step is decomposed in the second step. And at least one kind of metal element 3 (sometimes referred to as an introduced metal element or a specific metal element according to the context) contained in the compound 2 is introduced into the substrate 1. Then as a result a thin film 5 (FIG. 1(d)) is formed. In the present invention, as shown in FIGS. 1(e) to 1(g), the metal element 3 is further introduced into the formed thin film 5 by repeating alternately the first step and the second step.

On and after the second repetition, the formed thin film 5 acts as what is called “substrate 1” in the present invention and a compound is supplied onto this thin film 5, which is irradiated with energy particles. Therefore, on and after the second repetition of the first step and the second step, the thin film 5 acts as the substrate 1 and they become the same meaning.

Hereinafter, each composition is described while the first step and the second step are explained.

(First Step)

The first step is a step of supplying a compound 2 containing at least one kind of metal element 3 onto a substrate 1.

The substrate 1 is not particularly limited, provided it can have a metal element 3 in a compound 2 introduced into it and can have a thin film formed on it. And it is selected in consideration of a metal element to be introduced and constituent elements forming the substrate 1. For example, it is selected from a silicon substrate, a metal substrate other than silicon, an oxide substrate, a nitride substrate, an oxide nitride substrate and the like. And it may be a substrate composed of a semiconductor material such as germanium and the like or a substrate containing a semiconductor material.

In consideration of the practicality of a thin film understood at present, a substrate formed out of a material selected from a group consisting of silicon, silicon oxide, silicon nitride, silicon oxide nitride, aluminum oxide, aluminum nitride and aluminum oxide nitride is preferably used. As a concrete example, it is possible to use a silicon wafer, use a wafer obtained by performing an oxidation process, nitriding process or oxidation nitriding process on the surface of a silicon wafer or the like, or use a substrate obtained by performing an oxidation process, nitriding process or oxidation nitriding process on the surface of an aluminum film formed on a silicon wafer or the like. The state of crystallization of such a substrate may be either crystalline or amorphous, and is not particularly limited.

In the present invention, it is possible to form various functional thin films by selecting a material for the substrate 1 and the kind of an introduced metal element 3. For example, in case of using silicon for a substrate 1, it is possible to form a silicide film by introducing a metal element such as tungsten, molybdenum, titanium, tantalum, platinum or the like. And in case of using silicon oxide, silicon nitride or silicon oxide nitride for a substrate 1, it is possible to form a silicate film by introducing a metal element such as zirconium, hafnium, lanthanum or the like. And in case of using aluminum oxide, aluminum nitride or aluminum oxide nitride, it is possible to form an aluminate film by introducing a metal element such as zirconium, hafnium, lanthanum or the like.

The compound 2 is a compound (a) containing an introduced metal element 3 corresponding to the composition of a thin film to be formed, and further (b) having the property of being adsorbed onto a substrate after being supplied into a deposition chamber. Although such a compound is not particularly limited and can contain one, two or more kinds of metal elements to be introduced into a substrate, ordinarily an organometallic compound containing one kind of metal element 3 is preferably used.

As concrete examples of a compound 2, the compounds as follows can be selected.

As for (a) described above, there can be mentioned an organometallic compound containing a high-melting point metal (for example, tungsten, molybdenum, titanium, tantalum, platinum, etc.) for forming a silicide film, and an organometallic compound containing at least one metal element selected from a group consisting of zirconium, hafnium and lanthanoids for forming a silicate film or an aluminate film. And for (b) described above, for example, there are preferably used (1) an organometallic compound such as dimethylamino titanium, titanium tetrachloride, tetraxylidiethylamino titanium {Ti[N(CH₃)₂]₄}, trisdipivaloilmetanate cobalt {Co(C₁₁H₁₉O₂)₃}, pentaethoxy tantalum {Ta(OC₂H₅)₅}, hexafluoroacetylacetate platinum {Pt(C₅HF₆O₂)₂} and the like, (2) an organometallic compound of one kind selected from a group consisting of tertiary-butoxy hafnium {Hf(OtBu)₄}, acetylacetate hafnium {Hf(Acac)₄}, diethylamino hafnium {Hf(NEt₂)₄}, tertiary-butoxy zirconium {Zr(OtBu)₄}, acetylacetate zirconium {Zr(Acac)₄} and diethylamino zirconium {Zr(NEt₂)₄}, and (3) dipivaloilmetanate compound of one kind, for example dipivaloilmetanate (DPM) lanthanum {La(C₁₁H₁₉O₂)₃}, selected from a group consisting of lanthanum, terbium, erbium, holmium, dysprosium and praseodymium are preferably used.

Among the above compounds, an organometallic compound (1) is preferably used for forming a silicide film, and organometallic compounds (2) and (3) are preferably used for forming a silicate film or an aluminate film. Since compounds (2) and (3) contain oxygen and/or nitrogen, for example in case of containing oxygen, they can contribute to improvement of quality of a film by oxidation-removing contaminants such as carbon in the film in the second step described later. And in case of containing nitrogen, since they can form a nitrogen containing film, they can contribute to suppression of diffusion of boron (B) and the like.

In the first step, a compound to be adsorbed onto a substrate is supplied. The “necessary amount” of the compound is set in consideration of a substrate temperature, an equilibrium vapor pressure at that time, a gas partial pressure of a compound supplied, the staying time of the supplied compound in a reaction chamber and the like. Since it is possible to suppress a vapor-phase reaction between water and a compound inside a deposition chamber by keeping a moisture partial pressure in the reaction chamber 10−3 Pa or less for example, it is possible to make the compound to be stably adsorbed onto the substrate. And it is possible also to make a compound to be stably adsorbed onto the substrate by setting the temperature of the compound at a temperature at which the compound is not self-decomposed. For example, in case of using tertiary-butoxy hafnium being an organometallic compound, it is preferable to set the temperature of a substrate within a range from a room temperature (20° C. or higher) to 300° C. More concretely, this is as described in an embodiment described later. An adsorbed metal element in a compound is easily introduced into a substrate by the second step described later.

It is preferable that a compound is saturation-adsorbed onto a substrate. A compound saturation-adsorbed onto a substrate can make a metal element contained in the compound be uniformly introduced into the substrate by the second step described later. What is called “saturation-adsorption” in this case means a state where the surface of a substrate is uniformly occupied by a compound supplied and adsorption of the compound onto the substrate has reached saturation. It is namely, the state where the compound exists on the substrate in a very uniform state. Particularly, since any of the above-mentioned compounds is an organometallic compound having a large steric hindrance, even in case that many organometallic compounds are deposited on a substrate, at least an introduced metal element in an organometallic compound adsorbed onto the substrate is introduced into the substrate.

Next, a means for supplying a compound in the first step is described.

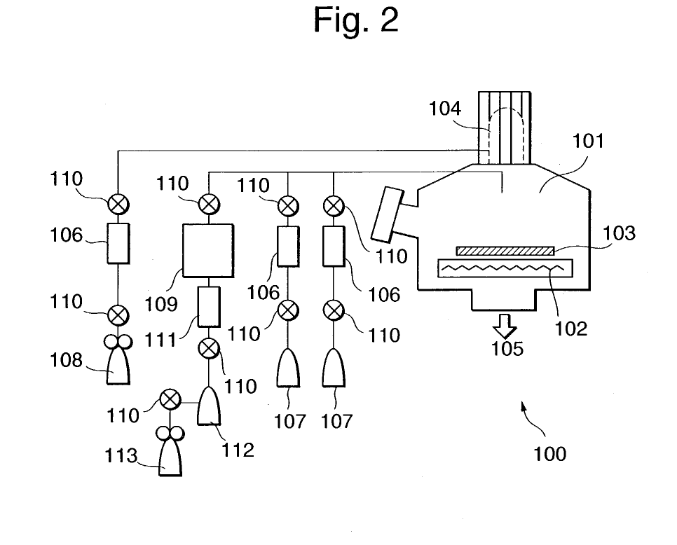

FIG. 2 is a schematic diagram showing an example of a thin film forming apparatus 100 used in a thin film forming method of the present invention. A deposition chamber 101 is evacuated by a vacuum pump 105 consisting of a dry pump, a drug molecular pump or the like and is kept at a reduced pressure. A base vacuum in the deposition chamber is 10−4 Pa or less and the moisture partial pressure is always kept at 10−3 Pa or less. In case that the base vacuum and the moisture partial pressure exceed these values respectively, an ordinary CVD reaction occurs with the residual moisture. A radical source 104 is mounted on the top of the apparatus, and plasma is generated by applying a microwave to the radical source 104. The radical source 104 is mounted with a gas cylinder 108. It is for supplying an inert gas such as argon or a mixed gas of an inert gas such as argon and oxygen and/or nitrogen through a stop valve 110 and a mass flow controller 106. And this thin film forming apparatus 100 is mounted with a heater 102 for heating a substrate 103, and the substrate 103 is heated by the heater 102. In this thin film forming apparatus 100, a compound is supplied onto a substrate by the following two means.

A first supply means is a supply means of heating a liquid compound to a specified temperature to raise its vapor pressure to come to be in a gaseous state and introducing the compound into the deposition chamber 101 through the mass flow controller 106. In order to supply a gaseous compound onto the substrate 103 by this first supply means, the apparatus 100 is provided with a channel of supply composed of a material cylinder 107 with a heating mechanism, a mass flow controller 106 and a stop valve 110.

A second supply means is a supply means of controlling the amount of liquid compound by means of a liquid mass flow controller 111 and then vaporizing and introducing the liquid by means of a carburetor 109 into the deposition chamber 101. In order to supply a gaseous compound onto the substrate 103 by the second supply means, the apparatus 100 is provided with a channel of supply consisting of a liquid material cylinder 112, a helium gas cylinder 113, a liquid mass flow controller 111, a carburetor 109 and a stop valve 110.

In these two supply means, the first supply means using the mass flow controller 106 is preferably applied to a compound which can be easily raised in vapor pressure by heating (for example, tertiary butoxide and the like), and the second supply means using the carburetor 109 is preferably applied to a compound being low in vapor pressure (for example, dipivaloilmetanate (DPM) and the like). (Second step)

The second step is a step of irradiating a substrate 1 with energy particles 4 in FIG. 1. The energy particles 4 irradiated in this second step act so as to decompose a compound 2 supplied onto a substrate 1 in the first step described above and introduce at least one kind of metal element 3 contained in the compound 2 into the substrate 1.

The energy particles 4 may be any energy particles having the abovementioned action, and various energy particles can be applied, and for example plasma, ions, radicals, electron beam, ultraviolet rays (including vacuum ultraviolet rays (excimer) also), X-rays and the like can be applied. When proper energy particles are selected from among such energy particles, they are selected considering whether or not a metal element in a compound can be introduced into a substrate by irradiating the energy particles and further considering deposition conditions such as a substrate temperature and the like. Ordinarily, plasma is preferably selected.

Plasma is a state of matter being electrically neutral due to coexistence of positive and negative charged particles, and the kind of it is selected in consideration of the composition of a thin film to be finally formed. For example, it is preferable that the kind of plasma is one kind of plasma selected from a group consisting of plasma obtained by exciting an inert gas, plasma obtained by exciting a mixed gas of an inert gas and oxygen, plasma obtained by exciting a mixed gas of an inert gas and nitrogen, plasma obtained by exciting a mixed gas of an inert gas, oxygen and nitrogen, and plasma obtained by exciting nitrogen. And these kinds of plasma may contain a small amount (0.1 to 10% or so) of hydrogen, and the hydrogen acts so as to prevent carbon contamination by removing carbon in a thin film through bonding with carbon. Generally nitrogen is classified as an inert gas, but since nitrogen acts as a reactive material in the present invention, it is not classified into an inert gas in the present invention. Therefore, an inert gas in the present invention means a rare gas (element in the 18th group) such as helium, neon, argon, krypton, xenon or the like, and preferably in particular it is argon.

Plasma obtained by exciting only an inert gas is preferably utilized in case of forming a silicide film. In this case, it is preferable that a supplied compound also is a compound containing neither oxygen nor nitrogen in its chemical structure.

Plasma containing oxygen has an advantage that contaminants such as carbon and the like in a formed thin film is oxidized and removed by the action of oxygen and as a result the film is made compact. And plasma containing nitrogen or nitrogen plasma has another advantage. It is that a different kind of atoms such as boron be suppressed from diffusion by the action of nitrogen, since nitrogen is taken into a substrate and a nitrogen containing silicate film or a nitrogen containing aluminates film is formed. In case of plasma obtained by exciting a mixed gas, the content rate of oxygen or nitrogen in the mixed gas is determined in consideration of the action of gases mixed, and a preferable content rate of oxygen is 0.1 to 50% and a preferable content rate of nitrogen is 1 to 100% (including the case of nitrogen only).

It is preferable that the conditions of irradiation of energy particles are determined so that a compound adsorbed onto a substrate is decomposed and a metal element contained in the compound is all introduced into the substrate by irradiation of the energy particles. As a result of doing so, the atomic content of an introduced metal element depends on only the amount of adsorption of a compound adsorbed onto the surface of the substrate, and the in-wafer uniformity of the introduced metal element can be made very high. In case of using argon plasma as energy particles, a preferable condition is that the pressure of generating plasma is 10−4 to 10 Pa, preferably 10−3 to 10 Pa, the density of plasma power is 0.001 to 1 W/cm², preferably 0.01 to 1 W/cm². Under such a plasma condition, a compound adsorbed onto a substrate is decomposed by plasma and a metal element contained in the compound is introduced into the substrate.

(Repetition of Each Step)

The atomic content of a metal element introduced into a substrate by each one operation of the respective first and second steps depends on the amount of adsorption of a compound adsorbed onto the surface of the substrate. Therefore, the atomic content of an introduced metal element can be increased by repeating the first step and the second step. After a thin film has been formed by a fact that a metal element has been introduced into a substrate, the thin film acts as a substrate (in this case, a thin film means the same as a substrate), and the respective steps are repeated again in order of the first step to the second step. The each first step and the each second step may repeat alternatively or every several times.

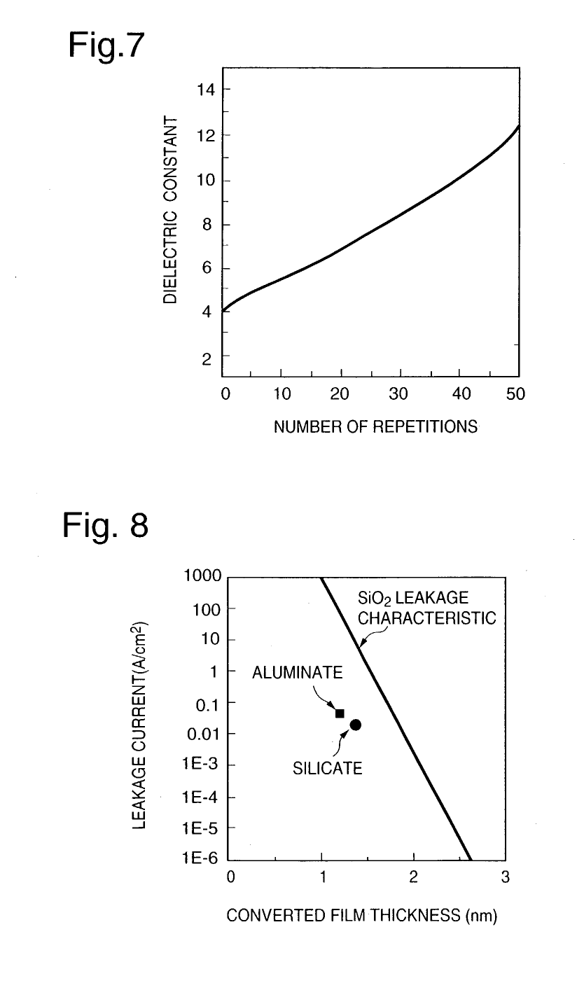

The atomic content of a metal element in a thin film formed is increased gradually by such repetitions. For example, in case of introducing a metal element such as zirconium, hafnium or the like into a silicon oxide substrate, by repeating the respective steps it is possible to gradually increase the atomic content of the metal element such as zirconium, hafnium or the like and gradually raise the permittivity of the formed thin film (see FIGS. 6 and 7 described later).

In a thin film forming method of the present invention, a step of supplying a compound containing a metal element of a different kind from a metal element supplied in the first step can be applied at an optional timing in place of the first step. By applying such a step in place of the first step, it is possible to introduce an optional amount of metal element other than a metal element supplied in the first step into a thin film.

Such a step may be applied alternately with the first step and may be applied every several operations or several-tens operations of the first step, and can be optionally set in consideration of the physical properties of a thin film to be formed. As a concrete example, an aluminum containing zirconium silicate film can be obtained by applying a step of supplying an organometallic compound containing aluminum (trimethylaluminum for example) at regular intervals in place of the first step of supplying an organometallic compound containing zirconium in process of forming a zirconium silicate film. This silicate film provides a more preferable characteristic since it contains aluminum having the action of suppressing crystallization and the action of suppressing the permeability of oxygen ion. And a hafnium containing zirconium silicate film can be also obtained by applying a step of supplying an organometallic compound containing hafnium (tertiary-butoxy-hafnium for example) at regular intervals. This silicate film has the action of preventing a film quality from being deteriorated at the time of depositing an upper polycrystalline silicon electrode.

And in the present invention, at the same time as the second step or after the second step, by performing a heat treatment in an oxygen atmosphere or an irradiation process of oxygen radicals, it is possible to oxidize carbon in a thin film and thereby reduce carbon impurities contained. In addition, it can make a silicate film compact due to improvement in film quality of compensation for oxygen deficient defects, or due to the increase of film density. And it may make a thin film contain nitrogen by performing an irradiation process of nitrogen radicals or mixed radicals of oxygen and nitrogen simultaneously with the second step or after the second step. Such a thin film contain nitrogen can make an effect to suppress the diffusion of boron (B) and the like. This is illustrated in FIG. 1(h).

(Method for Forming a Thin Film Through a Protective Film)

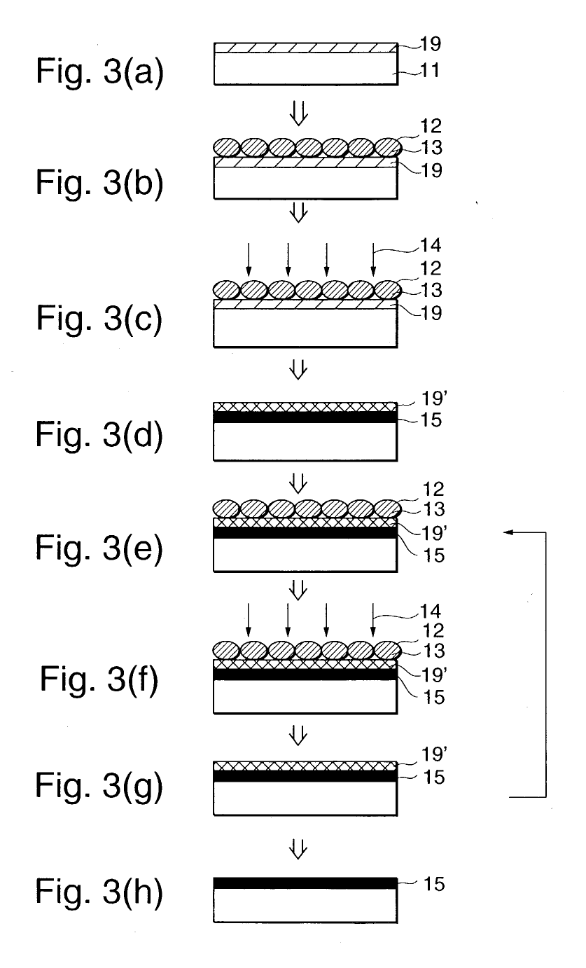

FIGS. 3(a) to (h) show another aspect of the thin film forming method of the present invention. This method concludes a first step of supplying a compound containing at least one kind of metal element onto a substrate having a protective film formed on it and a second step of irradiating the substrate with energy particles in order to introduce the metal element into the substrate, and thereafter removing said protective film.

According to this method, a compound containing a metal element is supplied through a substrate having a protective film 19 in the first step as shown in FIG. 3(b). And a metal element is introduced onto the substrate in the second step as shown in FIG. 3(c). And the first step and the second step are repeated as described above on a substrate 11 having a protective film 19 formed on it as shown in FIGS. 3(a) to 3(g). And thereafter the protective film 19′ is removed as shown in FIG. 3(h). Hereupon, a protective film denoted by symbol 19 means a protective film formed in advance in an initial state. And a protective film denoted by symbol 19′ means a protective film after the first step and the second step have been performed at least once respectively and an introduced metal element has been contained.

According to this thin film forming method, a thin film 15 has been formed on a substrate 11 which appears after a protective film 19′ has been removed.

This method can make a special effect of being capable of preventing contaminants from being introduced into a thin film 15 and of forming a thin film being little in damage and uniform in quality. The reason is that the metal element 13 is introduced into a substrate 11 through protective films 19 and 19′, and thanks to the action of the protective films 19 and 19′ it can prevent elements other than the introduced metal element 13 from being introduced into the substrate. In addition, it can assist against damaging the interface of a silicon substrate, against an increase of roughness, and against the formation of defects in an insulating film.

This thin film forming method forms, for example, a silicon oxide to be formed by performing a thermal oxidation process on a silicon substrate as a protective film 19 on the silicon substrate. And it supplies a compound 2 containing at least one kind of metal element 3 onto the silicon substrate having the protective film 19 formed on it (first step), and then irradiates the silicon substrate having the protective film 19 formed on it with energy particles (second step). At this time, the compound is decomposed and at least one kind of metal element contained in the compound is introduced into the protective film and the silicon substrate. After this, by performing a heat treatment in nitrogen for example, a silicide film is formed between the element introduced into the silicon substrate and silicon. A silicide film formed in such a manner is little in damage and in contamination thanks to the action of the protective films 19 and 19′.

As a protective film 19, there can be mentioned a silicon oxide film, a silicon nitride film, a silicon oxide nitride film and the like formed on a silicon substrate. And a compound in this method can be selected from among various compounds described above, and in case of forming a silicide film an organometallic compound containing a high-melting point metal such as tungsten, molybdenum, titanium, tantalum, platinum or the like can be preferably used. And the other conditions in the first step and second step in this invention are the same as the conditions described in the first step and second step described above.

(Semiconductor Device)

A semiconductor device manufacturing method of the present invention is characterized by having a thin film forming method of the present invention described above in a process. The semiconductor device manufacturing method according to this invention has a thin film forming process being capable of forming a high permittivity insulating film composed of, for example, a silicide film having a high-melting point metal such as tungsten, molybdenum, titanium or the like introduced into it, or a silicate film or aluminate film having a specific metal element such as zirconium, hafnium or the like contained in it well in in-wafer uniformity of film thickness and film quality. It makes it possible to improve the integration degree of a semiconductor large scale integrated circuit such as an MOS transistor and the like.

[Embodiments]

A thin film forming method and a semiconductor device manufacturing method of the present invention are concretely described by way of exemplary embodiments. In the following, “%” representing the content of a metal element or a gaseous constituent element (oxygen, nitrogen, hydrogen or the like) means “atomic %”.

<First Embodiment>

A first embodiment is an example of forming a hafnium silicate film. As a substrate, a silicon oxide film of 1 nm in thickness formed on a silicon substrate by means of a thermal oxidation method was used. In the first step of supplying a compound onto this silicon oxide film, tertiary-butoxy hafnium {Hf(OtBu)₄} having hafnium as an introduced metal element was used as a compound. In the second step of irradiating a silicon oxide film being a substrate with energy particles, argon plasma was adopted as energy particles.

This embodiment formed a hafnium silicate film by repeating alternately the first step and the second step. First, this embodiment heated a substrate 103 to 300° C. and then controlled the temperature of it within a range of 295 to 305° C., and supplied tertiary-butoxy hafnium being an organometallic compound heated to about 80° C. into a deposition chamber 101 at a partial pressure of 100 Pa for one second through a mass flow controller 106 (see FIG. 2). The compound supplied into the deposition chamber 101 under such conditions was controlled so as to be uniform in amount of adsorption onto the substrate 103 without being self-decomposed. Next, this embodiment generated argon plasma being energy particles for five seconds by applying a power of 0.1 W/cm at a partial pressure of 1 Pa. It introduced a specified amount of hafnium atoms into the substrate by repeating alternately the first step and the second step in such a manner. Finally it irradiated the substrate with plasma of a mixed gas having oxygen of 50% contained in argon, reduced residual carbon in a silicate film of hafnium and compensated oxygen deficiency.

The following result was obtained in the first exemplary embodiment.

(1) The in-wafer uniformity of film quality and film thickness was excellent when the pressure in generating argon plasma was set within a range of 10−4 to 10 Pa. And when the power density of plasma was set within a range of 0.001 to 1 W/cm², the in-wafer uniformity of film quality and film thickness was excellent. When plasma was generated at a lower pressure or at a higher power density than the above values, damage occurred in the substrate and the increase in interface level density appeared.

(2) In case of irradiating argon plasma and then performing a heat treatment in an oxygen atmosphere, this embodiment generated argon plasma by applying a power of 0.1 W/cm² at a pressure of 1 Pa, irradiated the substrate with this plasma for 60 seconds and thereafter performed a heat treatment on the substrate in an oxygen atmosphere. As the conditions of the heat treatment, it was preferable that a heat treatment was performed for about 1 minute at a temperature of about 500 to 950° C. in a nitrogen or oxygen atmosphere or in vacuum, and a method of forming a thin film by means of a thin film forming apparatus described above and thereafter uninterruptedly performing a heat treatment in the same apparatus was more preferable. And in case of performing oxidation simultaneously with irradiation of argon plasma, plasma of a mixed gas of argon containing oxygen of about 3% was irradiated.

(3) In case of performing nitrogen simultaneously with irradiation of plasma, plasma of a mixed gas of argon containing nitrogen of about 3% was irradiated. In this case, a very small amount of nitrogen of 0.1% was contained in the film.

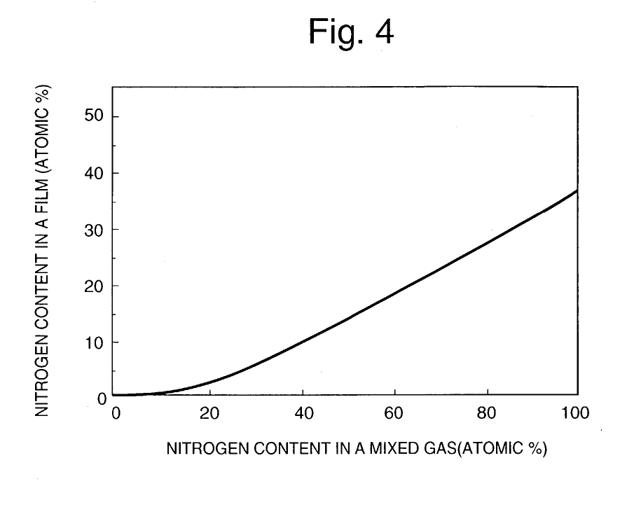

And as shown in FIG. 4, an effect of adding nitrogen in forming a hafnium silicate film was also examined. As shown in FIG. 4, the nitrogen content in the hafnium silicate film was also raised with the increase of the nitrogen content in the mixed gas. It was confirmed that oxygen was contained in a hafnium silicate film even in case of nitrogen of 100%, but this was influenced by oxygen contained in a silicon oxide and by oxygen contained in a tertiary-butoxy-hafnium material.

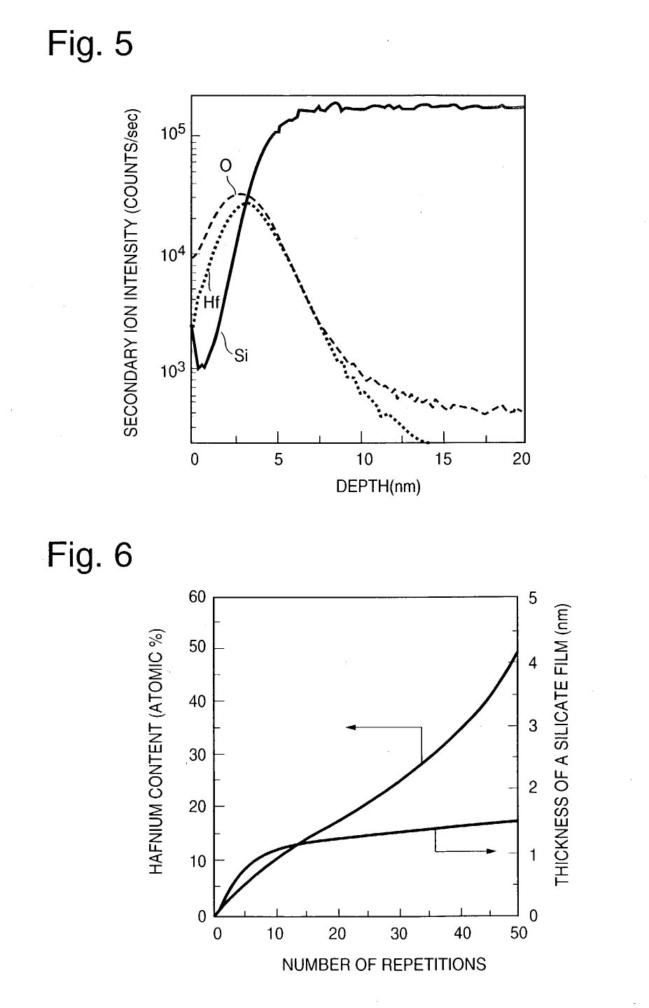

(4) This embodiment repeated 10 times the first step and the second step of irradiating argon plasma and thereafter performed a heat treatment in an oxygen atmosphere described above, and thereby formed a thin film. For the obtained thin film, the analysis in the direction of depth of constituent elements of the film was performed by means of a secondary ion mass spectrometry. FIG. 5 shows a result of the analysis. As a result of measuring the thickness of each layer on the silicon substrate by means of a cross sectional TEM observation, it was found that a silicate layer (film) of 1.1 nm was formed through an SiO₂ layer of 0.5 nm on the silicon substrate and further an excessive SiO₂ layer of 0.4 nm was formed on the surface.

(5) FIG. 6 is a diagram showing an influence of the number of repetitions of the first and second steps on the hafnium content in a silicate film formed and the thickness of the silicate film, and FIG. 7 is a diagram showing an influence of the number of repetitions of the first and second steps on the dielectric constant of the silicate film formed.

The hafnium content in a silicate film rose almost linearly with the increase of the number of repetitions. And the value of dielectric constant also rose almost linearly with the increase of the number of repetitions, and was changed continuously from the value of dielectric constant 4 of a silicon oxide having no hafnium introduced into it to the dielectric constant 12 in case of containing hafnium of 50%. Accordingly, it was possible to linearly increase the content of hafnium introduced into a silicon oxide film by repeating alternately the first step and the second step and thereby linearly increase the dielectric constant of a thin film. And the hafnium introduced in such a manner was introduced very uniformly into a silicon oxide film.

On the other hand, although the thickness of a silicate film slightly increases with the increase of the number of repetitions, it showed a trend of saturating above a certain film thickness. And a silicate film having a hafnium content of 50% or less gave rise to no crystallization even after a heat treatment of 1050° C. and further did not react with a polycrystalline silicon electrode over it, and was not found to be deteriorated.

(6) FIG. 8 shows the relation between a film thickness and an electric characteristic (leakage characteristic) in case of converting a hafnium silicate film formed by repeating the first step and second step 10 times into an SiO₂ film. The hafnium silicate film was more greatly reduced in leakage current in comparison with an SiO₂ film.

(7) The first embodiment of the present invention could completely suppress the vapor-phase reaction between a material and moisture by keeping the partial pressure of moisture within the deposition chamber 1 at a pressure of 10−3 Pa or less. Further, in this first embodiment, since an organometallic compound is saturation-adsorbed in essence and a metal element contained in the compound is uniformly introduced into a substrate by plasma irradiation, the in-wafer uniformity of film thickness and of an introduced metal element has been able to be made excellent.

The in-wafer distribution of film thickness was +0.1 nm or less in an 8-inch wafer as a result of measurement of film thickness by means of spectroscopic ellipsometry. When a similar film forming experiment was performed changing a substrate temperature to 350° C. and 400° C., an intense self-decomposition of an organometallic compound occurred at the above-mentioned temperatures and the uniformity in film quality and film thickness was damaged. The reason was that an organometallic compound was intensely self-decomposed at a temperature of 300° C. or higher and the growth by an ordinary CVD reaction progressed.

It was confirmed that a similar effect could be obtained also in case of using acetylacetate hafnium or diethylamide hafnium other than tertiary-butoxy hafnium, and a zirconium silicate film could be obtained in case of using tertiary-butoxy zirconium, acetlyacetate zirconium or diethylamide zirconium. In these materials, since an organometallic compound is intensely self-decomposed at a substrate temperature of 300° C. or higher, a good uniformity could be obtained at a substrate temperature of 300° C. or lower.

<Second Embodiment>

The second embodiment is an example of forming a hafnium aluminate film on a silicon substrate coated with an Al₂O₃ film. As a substrate, a silicon substrate having an Al₂O₃ film of 1 nm formed on it was used. This Al₂O₃ film was formed by an atomic layer deposition method using trimethylaluminum and H₂O as materials. In the first step of supplying a compound onto this Al₂O₃ film, the same tertiary-butoxy hafnium {Hf(OtBu)₄} as the first embodiment was used as a compound. In the second step of irradiating the Al₂O₃ film being a substrate with energy particles, argon plasma was adopted as energy particles.

This embodiment formed a hafnium aluminate film by repeating alternately the first step and the second step. This embodiment repeated alternately the first step and the second step under the same conditions as the first embodiment except performing the respective operations after heating first a substrate to 200° C. As a result similarly to the first embodiment, hafnium atoms were introduced into an Al₂O₃ film and a hafnium aluminate film was formed through the Al₂O₃ film on the silicon substrate.

In this second embodiment also, similarly to the first embodiment, the composition of a hafnium aluminate film could be changed from about 10% to about 50% by changing the number of repetitions from 10 to 60, and the value of dielectric constant at that time changed from about 10 to 20. In addition, hafnium aluminate film was more greatly reduced in leakage current in comparison with an SiO₂ film as showed in FIG. 8.

An aluminate film of a hafnium content of 50% or less produced no crystallization even after a heat treatment of 1050° C. and further did not react with a polycrystalline silicon electrode over it, and was not found to be deteriorated. With regard to the other conditions a thin film was formed under similar conditions to the first embodiment, and a similar result was obtained.

<Third Embodiment>

The third embodiment is an example of forming a lanthanum silicate film. As a substrate, a silicon oxide film of 1 nm in thickness formed on an 8-inch silicon substrate by means of a thermal oxidation method was used. In the first step of supplying a compound onto this silicon oxide film, dipivaloilmetanate (DPM) lanthanum {La(C₁₁H₁₉O₂)₃} was used as a compound. The DPM of lanthanum was white powder at a room temperature, and a solution having this powder dissolved at a concentration of 0.1 mol/L in butyl acetate was vaporized at a rate of 0.1 g/min and was supplied through a piping heated at a temperature of 200° C. or higher into the deposition chamber. The irradiation partial pressure of the lanthanum DPM was 100 Pa and argon plasma was generated by applying a power of 10 W at a partial pressure of 1 Pa. In the second step of irradiating the silicon oxide film with energy particles, argon plasma was adopted as energy particles.

This embodiment attempted to form a lanthanum silicate film by repeating alternately the first step and the second step. In this embodiment also, similarly to the first embodiment and the second embodiment, it was confirmed that lanthanum was introduced into a silicon oxide film and a lanthanum silicate film could be formed very well in uniformity.

A silicate film containing lanthanum of 50% did not react with a polycrystalline silicon electrode over it by heat treatment of 1050° C. and was not found to be deteriorated. Also in case of using a DPM compound of terbium, erbium, holmium, dysprosium or praseodymium other than lanthanum, a similar effect was obtained.

<Fourth Embodiment>

The fourth embodiment is an example of forming a lanthanum aluminate film. As a substrate, a silicon substrate having an Al₂O₃ film of 1 nm formed on it was used. Similarly to the second embodiment, this Al₂O₃ film was formed by an atomic layer deposition method using trimethylaluminum and H₂O as materials. In the first step of supplying a compound onto this Al₂O₃ film, dipivaloilmetanate (DPM) lanthanum {La(Cl H₁₉O₂)₃} was used as a compound similarly to the third embodiment. In the second step of irradiating the Al₂O₃ film being a substrate with energy particles, argon plasma was adopted as energy particles. The lanthanum DPM is the same as that of the third embodiment.

This embodiment formed a lanthanum silicate film by repeating alternately the first step and the second step. In this embodiment also, similarly to the first embodiment and the second embodiment described above, it was confirmed that lanthanum was introduced into alumina and a lanthanum aluminate film could be formed very well in uniformity.

An aluminate film containing lanthanum of 50% did not react with polycrystalline silicon over it by a heat treatment of 1050° C. and was not found to be deteriorated. Also in case of using a DPM compound of terbium, erbium, holmium, dysprosium or praseodymium other than lanthanum, a similar effect was obtained.

<Fifth Embodiment>

The fifth embodiment is an example of forming a titanium suicide film. A silicon substrate in which the native oxide film on the surface of it was removed by being immersed in 1%-dilute hydrofluoric acid was used as a substrate. In the first step of supplying a compound onto this silicon substrate, tetraxyldiethylamino titanium {Ti[N(CH₃)₂]₄} being a compound having titanium as an introduced metal element and containing no oxygen was used. In the second step of irradiating the silicon substrate with energy particles, argon plasma was adopted as energy particles.

This embodiment formed a titanium silicide film by repeating alternately the first step and the second step 10 cycles. First, it heated the substrate to 300° C. and then controlled the heated substrate within a range of 295 to 305° C., and heated the tetraxyldiethylamino titanium being a compound to about 80° C. and supplied it into the deposition chamber for 1 second at a partial pressure of 100 Pa through a mass flow controller. Under such conditions in the deposition chamber the supplied compound was controlled so that it was uniform in quantity of adsorption onto the substrate without being self-decomposed. Next, argon plasma being energy particles was generated for 5 seconds by applying a power of 0.1 W/cm² at a partial pressure of 1 Pa. This embodiment introduced titanium into the substrate by repeating the first step and the second step 10 cycles in such a way. Finally it annealed this substrate in nitrogen at 500° C. for 10 minutes and thereby formed a titanium silicide film of about 1 nm in thickness.

<Sixth Embodiment>

The sixth embodiment is an example of forming a cobalt silicide film. A silicon substrate in which the native oxide film on the surface of it was removed by being immersed in 1%-dilute hydrofluoric acid was used as a substrate similarly to the fifth embodiment. In the first step of supplying a compound onto this silicon substrate, trisdipivaloilmetanate cobalt {Co(C₁₁H₁₉O₂)₃} being a compound having cobalt as an introduced metal element was used as a compound. In the second step of irradiating the silicon substrate with energy particles, argon plasma was adopted as energy particles.

This embodiment formed a cobalt silicide film by repeating alternately the first step and the second step 10 cycles in a similar method to the fifth embodiment. The trisdipivaloilmetanate cobalt was white powder at a room temperature similarly to lanthanum of the third embodiment, and a solution having this powder dissolved at a concentration of 0.1 mol/L in butyl acetate was vaporized at a rate of 0.1 g/min and was supplied through a piping heated to a temperature of 200° C. or higher into the deposition chamber. The irradiation partial pressure of the cobalt compound was 100 Pa and argon plasma was generated by applying a power of 10 W at a partial pressure of 1 Pa.

This embodiment introduced cobalt into the silicon substrate by repeating the first and second steps 10 cycles in such a way. Finally it annealed this substrate in nitrogen at 500° C. for 10 minutes and thereby formed a cobalt silicide film of about 1 nm in thickness.

<Seventh Embodiment>

The seventh embodiment is an example of forming a titanium silicide film through a protective film. A silicon substrate in which the native oxide film on the surface of it was removed by being immersed in 1%-dilute hydrofluoric acid and then a rapid thermal oxidation was performed for 4 seconds at 850° C. in an oxygen atmosphere and thereby a silicon oxide film of 1.5 nm in thickness was formed was used as a substrate. In the first step of supplying a compound onto this silicon substrate having this silicon oxide formed on it, tetraxyldiethylamino titanium {Ti[N(CH₃)₂]₄} being a compound having titanium as an introduced metal element and containing no oxygen was used as a compound. In the second step of irradiating the silicon substrate having a silicon oxide formed on it, argon plasma was adopted as energy particles.

This embodiment formed a titanium silicide film by repeating alternately the first step and the second step 10 cycles. The conditions of it were the same as the fifth embodiment. Finally it annealed this substrate in nitrogen at 500° C. for 10 minutes. The silicon oxide also had titanium introduced into it and was formed into silicate, and a titanium silicide film of about 0.5 nm in thickness was formed on the silicon substrate.

The silicate layer (film) was dissolved and removed by 1%-dilute hydrofluoric acid and thereby a titanium silicide film was exposed. Since the formed titanium silicide film was processed through a silicon oxide, it could be formed into silicate without being damaged to the utmost.

<Eighth Embodiment>

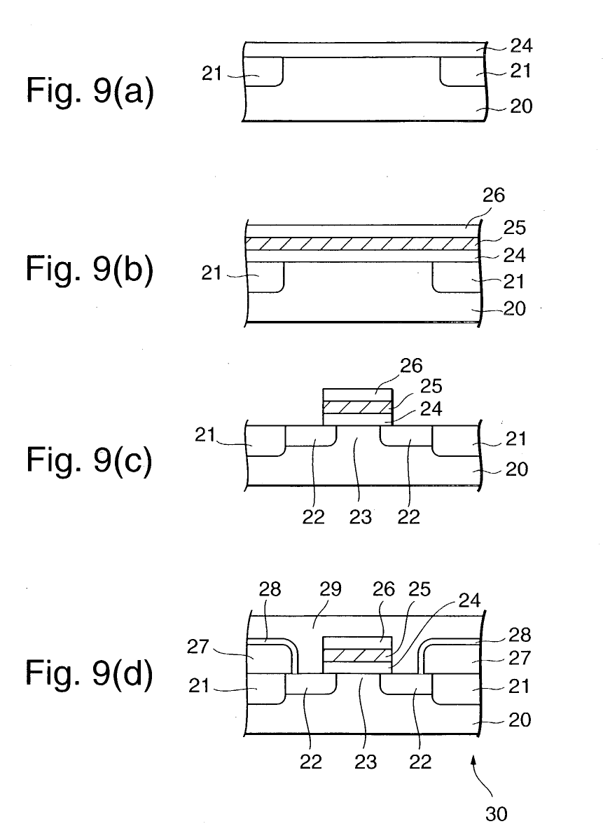

The eighth embodiment is an example of a method for manufacturing a semiconductor device 30 having a thin film-forming method of the present invention in a process. (FIGS. 9(a) to (d))

FIG. 9(d) is a sectional view of an n type transistor according to the eighth embodiment. A device isolation region 21 of an STI structure is formed on an n type single crystal silicon substrate of about 5×1015 cm−3 in impurity concentration. And a p well (not illustrated) is formed in an n type transistor forming region. A p type channel impurity layer of about 5×1016 cm−3 in impurity concentration for controlling a threshold value is formed (not illustrated) in a transistor region isolated by this device isolation region 21, and a source-drain region 22 composed of an n type diffused layer of about 5×10¹⁹ cm⁻³ in impurity concentration is formed. A silicate film 25 is formed through a silicon oxide film 24 (0.5 nm in film thickness) on a channel region 23. A gate electrode 26 composed of polycrystalline silicon and tungsten is formed on the silicate film 25. And a source electrode and drain electrode 28 each electrically conducting to a source-drain region 22 through a contact hole provided in an interlayer dielectric 27 are formed. Further, the whole transistor is covered with a passivation film 29.

A method for manufacturing an n type single transistor is described in order with reference to FIG. 9 in the following.

First, this method cleans the surface of an n type single crystal silicon substrate 21 by means of a cleaning method using a mixed aqueous solution of hydrogen peroxide, ammonia and hydrochloric acid. Since this cleaning aims at cleaning the surface of a single crystal silicon substrate 20, it is a matter of course that a method other than the above-mentioned method may be used. Next this method forms a p well in the silicon substrate and then makes a groove in the silicon substrate 20 by means of an RIE (reactive ion etch) method, and buries the groove with an insulating film and thereby forms a trench type device isolation region 21. Following this, this method forms a silicon oxide film 24 of 1 nm in thickness and then forms a p type channel impurity layer (not illustrated) by channel ion implantation (FIG. 9(a)). Further, it activates the p type channel impurity layer by RTA (rapid thermal anneal) at 800° C. for about 10 seconds (FIG. 9(a)).

Next, this method forms a hafnium silicate film 25 by means of a thin film forming method according to the present invention. It formed a silicate film 25 containing hafnium of about 10% by repeating alternately the first step of supplying a compound and the second step of irradiating argon plasma 10 times. Following this, it reduced carbon in the film and compensated for oxygen deficiency by irradiation of oxygen radicals and heat treatment in an oxygen atmosphere at 750° C. for 10 minutes. By the above-described process, a silicate layer (film) of 1.1 nm was formed through an SiO₂ layer of 0.5 nm on the silicon substrate and an SiO₂ rich layer of 0.4 nm was formed on the top surface.

Next, this method forms a gate electrode 26 composed of polycrystalline silicon by means of a low pressure vapor deposition method (LPCVD). It forms a photoresist pattern (not illustrated) on the gate electrode (polycrystalline silicon) 26 formed in such a manner, and patterns the gate electrode 26, the silicate film 25 and the silicon oxide film 24 by means of an anisotropic etching method using this pattern as an etching mask (FIG. 9(b)).

Next, this method uses the photoresist pattern, the gate electrode 26, the silicate film 25 and the silicon oxide film 24 as a mask for ion implantation, and forms a source-drain region 22 so as to be self-aligned by implanting arsenic being impurity ions into the silicon substrate 20 (FIG. 9(c)).

Next, this method removes the photoresist pattern and performs a heat treatment (in a nitrogen atmosphere of 1 atm at 1000° C. for 1 second) for activating the source-drain region 22 and the gate region 26. Next, it forms an interlayer dielectric 27. Next, it forms a contact hole reaching the source-drain region 22 and the gate electrode 26, deposits Co and TiN (not illustrated), performs RTA (rapid thermal anneal) in nitrogen at 700° C. for 10 seconds, and then patterns this and forms a specified source electrode 28 and gate electrode 26 (FIG. 9(d)).

Further, this method performs an annealing process in an atmosphere having a ratio of nitrogen vs. oxygen of 9:1 at 400° C. for 10 minutes and finally forms a passivation film 29 on the whole transistor and thereby obtains a semiconductor device 30 shown in FIG. 9(d).

The interface level density of the interface between the silicate film 25 being a gate insulating film and the gate electrode (polycrystalline silicon) 26 of the transistor made by the above-described process was 7×10¹⁰/cm² eV and was nearly equal to the interface level density of the interface between a silicon oxide film and a gate electrode formed by an ordinary thermal oxidation process. The reason is that since a silicate film 25 is formed through a thin silicon oxide film in the present invention, occurrence of damage can be reduced. The gate capacity of the transistor was about double in comparison with that in case of using a silicon oxide film having the same film thickness, and an effect of using a high permittivity insulating film for a gate was proved. When the operation of a transistor made in such a way was confirmed, the transistor showed a normal operation. In a thin film forming method of the present invention, since particularly the in-wafer uniformity of a silicate film 25 being a gate insulating film is excellent, it has been possible to suppress the in-wafer variations of a threshold voltage caused by fluctuation in film thickness within 1%, and suppress also the in-wafer variations of drain current caused by fluctuation in film thickness within 1%.

And in the structure of a semiconductor device 30 described above, even in case of using a silicon-germanium compound crystal as the gate electrode 26, a similar effect to the case of using polycrystalline silicon described above was obtained. When a similar transistor was made using a hafnium aluminate film or a zirconium or lanthanum aluminate or silicate film, the transistor showed a normal operation and provided a similar effect.

<Ninth Embodiment>

The ninth embodiment also is an example of a semiconductor device manufacturing method having a thin film forming method of the present invention in a process.

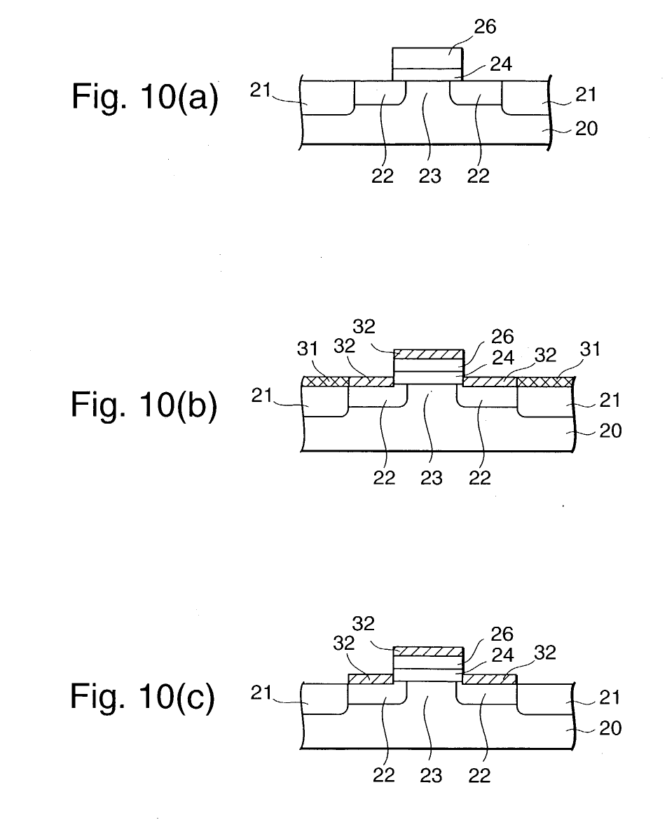

Similarly to the eighth embodiment, FIG. 10 also is a sectional view of an n type transistor. In FIG. 10(a), a semiconductor device composed of a device isolation region 21, a source-drain region 22, a silicon oxide film 24 being a gate insulating film, a gate electrode 26 composed of polycrystalline silicon and a channel region 23 was formed in advance, and thereafter by applying a thin film forming method of the present invention, a silicate film 31 was formed on the device isolation region 21, and silicide films 32 were formed on the source-drain region 22 and the gate electrode 26 (FIG. 10(b)). After this, the silicate film 31 formed on the device isolation region 21 was removed by a hydrofluoric acid solution of about 1% in concentration, and thereby a semiconductor device 20 shown in FIG. 10(c) was manufactured.

What is claimed is:

1. A thin film forming method characterized by at least a first step and a second step;
the first step of supplying a compound containing at least one kind of metal element onto a substrate, and
the second step of irradiating said substrate with energy particles in order to introduce said metal element into said substrate.

2. A thin film forming method according to claim 1,
wherein in said first step, at least a necessary amount of said compound to be adsorbed onto said substrate is supplied.

3. A thin film forming method according to claim 2,
wherein in said first step, said compound is saturation-adsorbed onto said substrate.

4. A thin film forming method according to claim 3,
wherein in said second step, said energy particles are plasma.

5. A thin film forming method according to claim 4,
wherein said plasma is selected from a group comprising of plasma obtained by exciting an inert gas, plasma obtained by exciting a mixed gas of an inert gas and oxygen, plasma obtained by exciting a mixed gas of an inert gas and nitrogen, plasma obtained by exciting a mixed gas of an inert gas, oxygen and nitrogen, and plasma obtained by exciting nitrogen.

6. A thin film forming method according to claim 5, wherein said inert gas is argon.

7. A thin film forming method according to claim 6,
wherein said substrate is made of a material selected from a group comprising of silicon, silicon oxide, silicon nitride, silicon oxide nitride, aluminum oxide, aluminum nitride, and aluminum oxide nitride.

8. A thin film forming method according to claim 4, wherein said compound is a compound containing a high-melting point metal for forming a silicide film.

9. A thin film forming method according to claim 4, wherein said compound contains at least one kind of metal selected from a group consisting of zirconium, hafnium and lanthanoids.

10. A thin film forming method according to claim 8, wherein said compound is an organometallic compound containing oxygen and/or nitrogen.

11. A thin film forming method according to claim 9, wherein said compound is an organometallic compound containing oxygen and/or nitrogen.

12. A thin film forming method according to claim 1, wherein the permittivity of a thin film formed is made gradually higher by repeating the first step and the second step.

13. A thin film forming method according to claim 1,
further including a step of supplying another compound with a different kind of metal element from a metal element supplied with the compound in said first step onto said substrate is applied at an optional timing subsequent to said first step.

14. A thin film forming method according to claim 13,
wherein in said second step, said energy particles are plasma.

15. A thin film forming method according to claim 14,
wherein said substrate is made of a material selected from a group comprising of silicon, silicon oxide, silicon nitride, silicon oxide nitride, aluminum oxide, aluminum nitride, and aluminum oxide nitride.

16. A thin film forming method according to claim 15, wherein at least one of said compound and said another compound is a compound containing a high-melting point metal for forming a silicide film.

17. A thin film forming method according to claim 15, wherein at least one of said compound and said another compound contains at least one kind of metal selected from a group consisting of zirconium, hafnium and lanthanoids.

18. A thin film forming method according to claim 16, wherein at least one of said compound and said another compound is an organometallic compound containing oxygen and/or nitrogen.

19. A thin film forming method according to claim 17, wherein as least one of said compound and said another compound is an organometallic compound containing oxygen and/or nitrogen.

20. A thin film forming method characterized by a first step and a second step
the first step of supplying a compound containing at least one kind of metal element onto a substrate having a protective film formed on it, and
the second step of irradiating said substrate with energy particles in order to introduce said metal element onto said substrate, and thereafter removing said protective film.

21. A thin film forming method according to claim 20,
wherein a silicide film is formed on the substrate from which the protective film has been removed.

22. A semiconductor device manufacturing method for manufacturing a semiconductor device having a thin film, said method including;
forming said thin film according to the method of claim 1.

23. A thin film forming method according to claim 1,
wherein said first step and said second step are repeated.

24. A thin film forming method according to claim 20,
wherein said first step and said second step are repeated.
